(19) United States
(12) Patent Application Publication
(10) Pub. No.: US 2026/0302406 A1
(43) Pub. Date: Oct. 1, 2026

(54) ELECTRICITY STORAGE DEVICE EVALUATION APPARATUS AND USE THEREOF

(71) Applicant: Prime Planet Energy & Solutions, Inc., Tokyo (JP)

(72) Inventors: Kanaru HASHISAKE, Kobe-shi (JP); Takanori SOEJIMA, Toyota-shi (JP); Ryosuke IWATA, Kobe-shi (JP)

(21) Appl. No.: 19/574,433

(22) Filed: Mar. 23, 2026

(30) Foreign Application Priority Data
Mar. 28, 2025 (JP) 2025-054744

(51) Int. Cl. H01M 10/633; G01R 31/36; G01R 31/364; G01R 31/385; H01M 10/48; H01M 10/613; H01M 10/66

(52) U.S. Cl. CPC H01M 10/633; G01R 31/364; G01R 31/3644; H01M 10/486; H01M 10/613; H01M 10/66; G01R 31/385

(57) ABSTRACT

An evaluation apparatus for an electricity storage device includes electrically conductive probes, a cooling mechanism, and a controller. The probes are attached to the electricity storage device such that the probes abut against terminals exposed outside the electricity storage device. The cooling mechanism is configured to blow cooling air onto the probes, with the probes being attached to the terminals and. The controller detects a temperature of the terminals of the electricity storage device. The controller adjusts an airflow rate of the cooling air in response to a temperature increase of the terminals, which is calculated based on a temporal change in the measured temperature of the terminals.

### CROSS REFERENCE TO RELATED APPLICATIONS

The present application claims the benefit of priority to Japanese Patent Application No. 2025-054744 filed on Mar. 28, 2025. The entire contents of this application are hereby incorporated herein by reference.

### BACKGROUND

### Technical Field

The present disclosure relates to electricity storage device evaluation apparatuses and electric characteristic measuring methods using the apparatuses.

### Background Art

Before being commercially distributed, electricity storage devices, such as secondary batteries, undergo tests, such as charging and discharging tests, so that their characteristics, such as resistance values, are evaluated. JP H08-007933 A, for example, discloses a battery container for use in an apparatus to test and evaluate various characteristics of a secondary battery during charging and discharging. The battery container includes a positive electrode terminal and a negative electrode terminal, which are connected to a charger/discharger that monitors, for example, an electric current. The battery container internally includes a heater and a cooling pipe integrated inside the battery container so as to heat or cool the inside of the container. A battery housed in the battery container undergoes a charging and discharging test, with the battery being wire-connected to the positive electrode terminal and the negative electrode terminal. JP H08-007933 A suggests that an environmental temperature during the test is controllable using the heater and the cooling pipe.

JP 2017-120747 A discloses a nickel-metal hydride secondary battery cooling apparatus. The cooling apparatus includes a cooling fan to supply cooling air to a nickel-metal hydride secondary battery. The cooling apparatus measures an electric current flowing through the nickel-metal hydride secondary battery, and adjusts an airflow rate of cooling air, which is supplied from the cooling fan, based on a magnitude of a heat generation index calculated from the measured electric current.

### SUMMARY

Techniques disclosed in JP H08-007933 A and JP 2017-120747 A described above, however, do not indicate specific locations where cooling should occur, resulting in low cooling efficiency. This induces insufficient cooling and/or excessive cooling, which may unfortunately lead to a failure to reproduce a temperature behavior observed during actual use.

Accordingly, techniques of the present disclosure provide electricity storage device evaluation apparatuses, electricity storage device evaluation methods, and electricity storage device manufacturing methods, which will be described below.

[1]

An electricity storage device evaluation apparatus comprising: an electrically conductive probe; a cooling mechanism; and a controller, wherein the probe is attached to an electricity storage device such that the probe abuts against a terminal exposed outside the electricity storage device, the cooling mechanism is configured to blow cooling air onto the probe, with the probe being attached to the terminal, the controller detects a temperature of the terminal of the electricity storage device, and based on the temperature of the terminal, the controller adjusts an airflow rate of the cooling air supplied from the cooling mechanism.

[2]

The electricity storage device evaluation apparatus according to [1], wherein the probe includes a contact portion that comes into direct contact with the terminal of the electricity storage device, and a lateral surface extending in a longitudinal direction of the probe, and the cooling mechanism includes a cooling fan to generate cooling air for cooling the probe, and an outlet facing the lateral surface of the probe.

[3]

The electricity storage device evaluation apparatus according to [2], wherein the probe has an area of 400 mm² or more in a vertical cross-section that passes through its central axis extending in the longitudinal direction of the probe and that faces the outlet.

[4]

The electricity storage device evaluation apparatus according to any one of [1] to [3], wherein the lateral surface of the probe is provided with a fin for heat dissipation.

[5]

The electricity storage device evaluation apparatus according to any one of [1] to [4], wherein the cooling mechanism is able to supply the cooling air to the probe at an airflow rate of 1 m³/min or more.

[6]

An electricity storage device evaluation method comprising: bringing a probe into abutment with a terminal of an electricity storage device and placing a cooling mechanism such that cooling air is blown onto the probe; supplying a predetermined electric current or voltage to the electricity storage device so as to charge or discharge the electricity storage device; measuring a temperature of the terminal of the electricity storage device during charging or discharging; calculating a temperature increase of the terminal based on a temporal change in the measured temperature of the terminal; and changing an airflow rate of the cooling air in response to the calculated temperature increase.

[7]

The electricity storage device evaluation method according to [6], wherein changing the airflow rate of the cooling air includes performing feedback control to change the airflow rate of the cooling air such that the temperature increase approximates that observed in a temperature change model obtained in advance.

The techniques of the present disclosure enable localized cooling of regions that generate a high amount of heat during evaluation test of the electricity storage device. This enhances the efficiency of cooling the electricity storage device. Accordingly, the evaluation test is conducted in an environment where a temperature behavior of the electricity storage device approximates that observed during actual use. Consequently, the techniques of the present disclosure enable simple and accurate evaluation of the electricity storage device.

### BRIEF DESCRIPTION OF THE DRAWINGS

FIG. 1 is a perspective view of an electricity storage device according to one embodiment.

FIG. 2 is a perspective view schematically illustrating an exemplary state of the electricity storage device during evaluation.

FIG. 3 is a side view schematically illustrating a condition of an evaluation apparatus during operation.

FIG. 4 is an explanatory diagram schematically illustrating an exemplary installation method for the evaluation apparatus and the electricity storage device.

FIG. 5 is a schematic diagram of a probe according to said one embodiment.

FIG. 6 is a vertical cross-sectional view of the probe according to said one embodiment.

FIG. 7 is a flow chart of an electricity storage device evaluation method that uses an electricity storage device evaluation apparatus disclosed herein.

FIG. 8 is a functional block diagram of an electricity storage device evaluation apparatus according to one aspect disclosed herein.

FIG. 9 is a graph illustrating changes in terminal temperature of the electricity storage device in the 1st cycle.

FIG. 10 is a graph illustrating changes in temperature of a bottom surface of the electricity storage device in the 1st cycle.

FIG. 11 is a graph illustrating changes in resistance increase rate of the electricity storage device during charging and discharging test.

FIG. 12 is a graph illustrating a relationship between an increase in terminal temperature of the electricity storage device and an airflow rate of cooling air.

FIG. 13 is a temperature contour diagram generated from CAE analysis conducted on the electricity storage device that has not undergone temperature adjustment by a cooling mechanism.

FIG. 14 is a temperature contour diagram generated from CAE analysis conducted on the electricity storage device that has undergone temperature adjustment by the cooling mechanism.

### DETAILED DESCRIPTION

Preferred embodiments of evaluation apparatuses according to the present disclosure will be described in detail below. Matters other than those specified herein but necessary to implement the present disclosure (e.g., a configuration, structure, or arrangement of an electricity storage device) may be understood by those skilled in the art as design matters based on techniques known in this field. The present disclosure may be carried out based on what is described herein and common technical knowledge in this field.

### Definition of Terms

In the drawings of this specification, components and elements similar in function are identified by common reference signs. Dimensions (e.g., lengths, widths, and thicknesses) depicted in the drawings do not reflect actual dimensions. The reference signs L, R, U, D, F, and Rr in the drawings respectively represent left, right, up, down, front, and rear. The reference sign X represents a right-left direction. The reference sign Y represents an up-down direction. The reference sign Z represents a front-rear direction. These directions, however, are defined merely for the sake of convenience of description and do not limit in any way how the evaluation apparatus or other apparatus according to the present disclosure may be installed.

As used herein, any numerical range from “A” to “B” (where A and B are any numerical values) may be inclusive of A and B, may be greater than A and less than B, may be greater than A and less than or equal to B, and may be greater than or equal to A and less than B.

As used herein, ordinal terms such as “first”, “second”, and “third” are used to differentiate components that share the same name and do not imply any particular order or importance of the components.

As used herein, the term “electricity storage device” is a concept encompassing a device that is charged and discharged by movement of charge carriers between a pair of electrodes (i.e., positive and negative electrodes). Specifically, the term “electricity storage device” encompasses not only batteries, such as secondary batteries (e.g., lithium ion secondary batteries, nickel-metal hydride batteries, and nickel-cadmium batteries) but also capacitors (or physical batteries), such as lithium ion capacitors and electric double layer capacitors. As used herein, the term “lithium ion secondary battery” refers to an electricity storage device that involves using lithium ions as charge carriers and is repeatedly chargeable and dischargeable by movement of electric charges between positive and negative electrodes, which is accompanied by migration of the lithium ions.

As used herein, the term “probe” refers to any device that supplies an electric current, electric signal, or other signal to a test object from an electric current source or other source (e.g., a power supply), or receives an electric current, electric signal, or other signal from the test object so as to transmit the received electric current, electric signal, or other signal to a measuring device or other device. Typical examples of such a probe include: a current probe that passes an electric current; a voltage probe that applies a voltage; and a special probe. Examples of the special probe include an optical probe, a logic probe, and an ultrasound probe. Each probe disclosed herein may be of any type, provided it does not significantly limit effects achieved by techniques of the present disclosure. Any suitable type of probe may be selected in accordance with a test object to be used and a purpose of a test to be performed (e.g., based on what kind of signal is to be received from a measurement object). Each probe disclosed herein may be passive or active. Each probe disclosed herein may be used to input or output, for example, an electric current.

### Electricity Storage Device 1

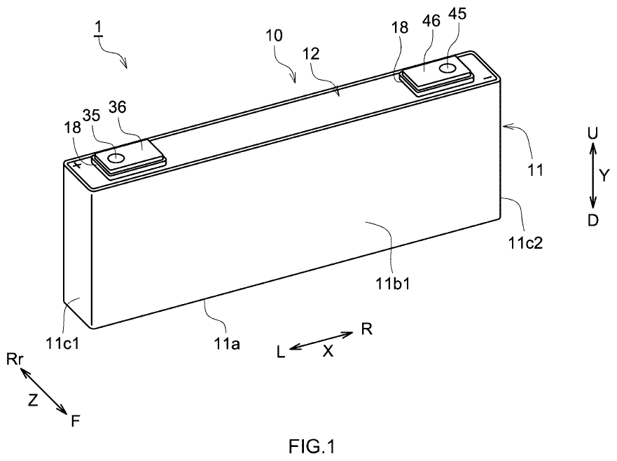

A preferred embodiment of the present disclosure will be described below with reference to the drawings. FIG. 1 is a perspective view of an electricity storage device 1 according to one embodiment. The electricity storage device 1 is a typical object to be evaluated by an evaluation apparatus 300 disclosed herein.

The electricity storage device 1 according to this embodiment includes a case 10 containing: an electrode assembly including a positive electrode and a negative electrode; and an electrolyte. As illustrated in FIG. 1, the case 10 has a flat cuboidal shape (or rectangular shape) with a closed bottom. The case 10 includes a body 11 and a sealing plate 12. The body 11 includes: a substantially rectangular bottom surface 11a with long sides and short sides; a pair of wide surfaces 11b1 and 11b2 extending from the long sides of the bottom surface 11a and facing each other; and a pair of narrow surfaces 11c1 and 11c2 extending from the short sides of the bottom surface 11a and facing each other. The sealing plate 12 is a plate-shaped member with long sides and short sides. The body 11 includes an opening facing the bottom surface 11a. The sealing plate 12 is attached to the body 11 so as to close the opening of the body 11. The case 10 is configured such that the sealing plate 12 is connected to a peripheral edge of the opening of the body 11 (e.g., by welding such as laser welding) and is thus integral therewith. As a result, the case 10 is sealed airtightly (or sealed hermetically). The sealing plate 12 faces the bottom surface 11a of the case 10. In this embodiment, the sealing plate 12 defines an upper surface of the case 10.

The case 10 may be made of any suitable material. Examples of the material for the case 10 include aluminum, an aluminum alloy, iron, an iron alloy, and stainless steel. The case 10 may be modified in configuration, structure, or arrangement. In one example, a laminated film exhibiting plasticity may be used as the case.

The case 10 includes positive and negative terminals 35 and 45 for external connection. As illustrated in FIG. 1, the positive and negative terminals 35 and 45 in this embodiment are fixed to the sealing plate 12 through gaskets 18. The positive terminal 35 is disposed on a first side (i.e., left side) in a lengthwise direction of the sealing plate 12. The negative terminal 45 is disposed on a second side (i.e., right side) in the lengthwise direction of the sealing plate 12. Although not illustrated in detail, an inner structure of the case 10 involves the positive terminal 35 electrically connected to the positive electrode inside the case 10. The negative terminal 45 is electrically connected to the negative electrode inside the case 10. These external terminals are made of electrically conductive metal. Aluminum or an alloy composed mainly of aluminum, for example, may be used as the positive terminal 35. Copper or a copper alloy, for example, may be used as the negative terminal 45. An insulating material that exhibits high chemical resistance and/or high weather resistance may be used as a material for the gaskets 18. In the following description, when no specific distinction between the positive terminal 35 and the negative terminal 45 is necessary, the positive terminal 35 and the negative terminal 45 may simply be referred to as “terminals 35, 45” for the sake of convenience.

As illustrated in FIG. 1, in this embodiment, a positive electrode external terminal conductive member 36 and a negative electrode external terminal conductive member 46, each having a plate shape, are attached to an outer surface of the sealing plate 12. The positive electrode external terminal conductive member 36 is electrically connected to the positive terminal 35. The negative electrode external terminal conductive member 46 is electrically connected to the negative terminal 45. The positive electrode external terminal conductive member 36 and the negative electrode external terminal conductive member 46 are preferably made of metal, and more preferably made of, for example, aluminum or an aluminum alloy. The positive electrode external terminal conductive member 36 and the negative electrode external terminal conductive member 46 are optional and may be omitted in other embodiments.

### Evaluation Apparatus 300

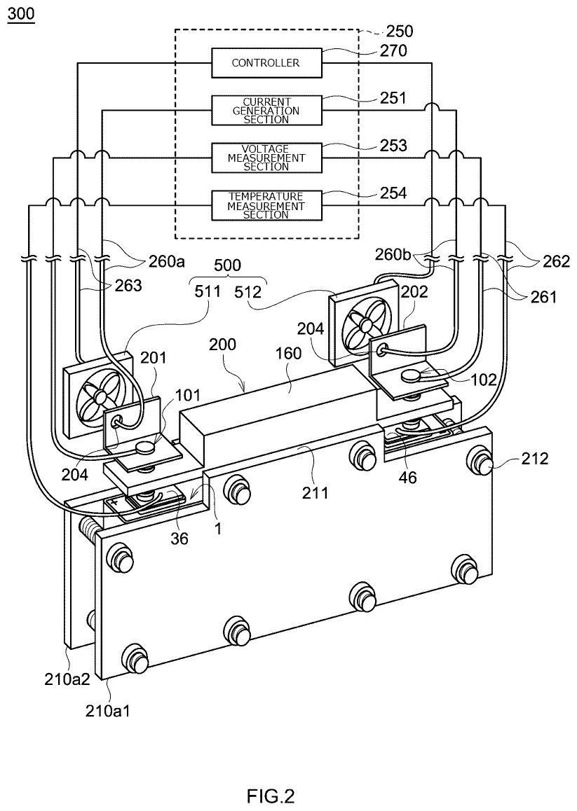

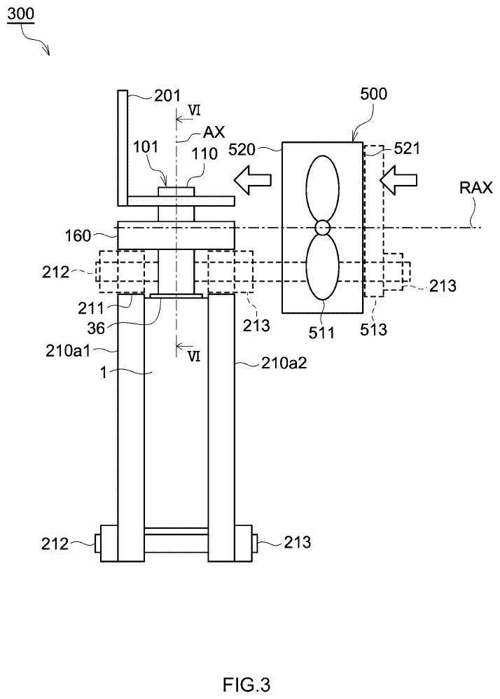

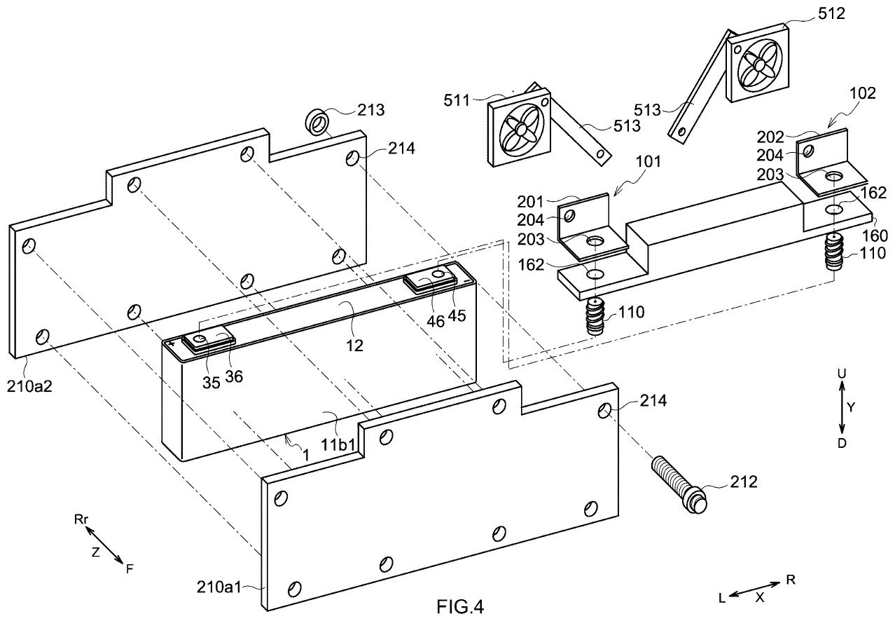

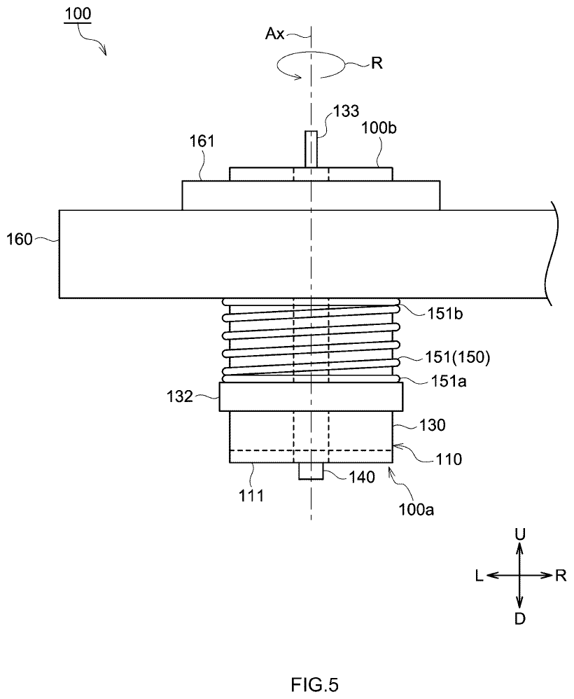

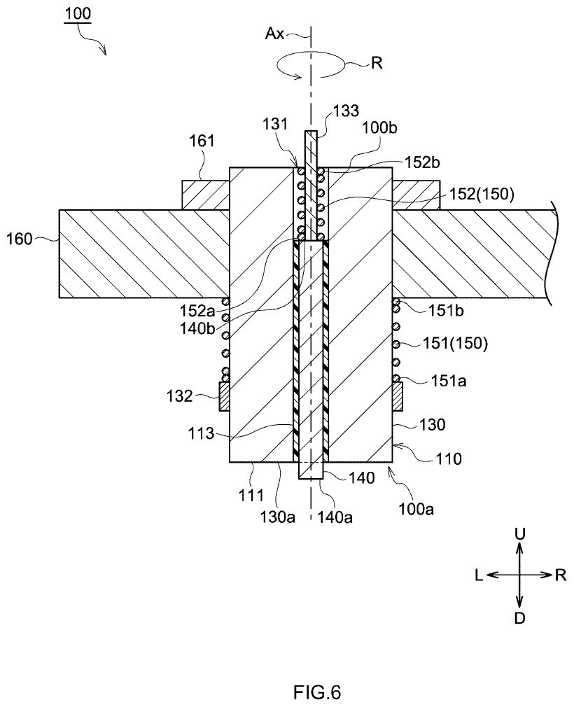

The evaluation apparatus 300 includes probes 100 (i.e., a first probe 101 and a second probe 102), a cooling mechanism 500, and a controller 270. The evaluation apparatus 300 evaluates various characteristics (e.g., a voltage) of the electricity storage device 1, which serves as a test object, during charging and discharging. FIG. 2 is a perspective view schematically illustrating a state of the electricity storage device 1 during evaluation. FIG. 3 is a side view schematically illustrating a condition of the evaluation apparatus 300 during operation. In FIG. 3, some components adjacent to the first probe 101 are rendered transparent to clarify a positional relationship between the first probe 101 and the cooling mechanism 500. FIG. 4 is an explanatory diagram schematically illustrating an exemplary installation method for the evaluation apparatus 300 and the electricity storage device 1. In FIG. 4, the evaluation apparatus 300 is disassembled to clarify how the evaluation apparatus 300 illustrated in FIG. 2 is to be attached to the electricity storage device 1. FIG. 5 is a schematic diagram of one of the probes 100 according to said one embodiment. FIG. 6 is a vertical cross-sectional view of one of the probes 100 according to said one embodiment.

### Probe 100

The probes 100 are electrically conductive. The probes 100 are electrically connected to the electricity storage device 1 by coming into contact with the terminals 35, 45 of the electricity storage device 1. As illustrated in FIG. 2, the probes 100 according to this embodiment include: the first probe 101 to be connected to the positive terminal 35; and the second probe 102 to be connected to the negative terminal 45. In the following description, when no distinction between the first probe 101 and the second probe 102 is necessary, the first probe 101 and the second probe 102 may each be simply referred to as the “probe 100” for the sake of convenience. In this embodiment, the first probe 101 and the second probe 102 share a bearing portion 160 and are included in a probe unit 200 in which the first and second probes 101 and 102 and the bearing portion 160 are integral with each other.

As illustrated in FIG. 4, the probes 100 include electrically conductive probe pins 110. Each probe pin 110 according to this embodiment includes a current supply probe pin 130 and a voltage detection probe pin 140. Each current supply probe pin 130 is able to receive or output an electric current of any magnitude from or to the electricity storage device 1. In other words, each current supply probe pin 130 serves as a current path for the electricity storage device 1. Each voltage detection probe pin 140 is able to measure a voltage of the electricity storage device 1. In other words, each voltage detection probe pin 140 serves as a voltage path for the electricity storage device 1. As illustrated in FIG. 5, each current supply probe pin 130 in this embodiment has a cylindrical shape (i.e., a hollow shape). Each current supply probe pin 130 includes a hollow portion 131 extending in a longitudinal direction of the probe 100 (i.e., the up-down direction Y). The current supply probe pins 130 are outwardly located components of the probe pins 110. Each voltage detection probe pin 140 has a circular columnar shape (or is formed into a solid round bar). Each voltage detection probe pin 140 is inserted into the hollow portion 131 of a corresponding one of the current supply probe pins 130. Each probe pin 110 according to this embodiment includes an insulator 113 insulating the current supply probe pin 130 and the voltage detection probe pin 140 from each other. Specifically, each voltage detection probe pin 140 is disposed inside the corresponding current supply probe pin 130, with the insulator 113 interposed therebetween. This prevents direct electrical conduction between each current supply probe pin 130 and the corresponding voltage detection probe pin 140. Thus, the probes 100 are able to measure the voltage of the test object while passing an electric current to the test object. The probe pins, however, are not limited to this arrangement. In one example, each current supply probe pin may be placed inside the corresponding voltage detection probe pin. Alternatively, exactly one type of probe pin or three or more types of probe pins may be used.

As illustrated in FIG. 5, each probe pin 110 includes a front end 100a and a rear end 100b located opposite to the front end 100a. A current wire and/or a probe terminal, for example, are/is attached to each rear end 100b. In this embodiment, each rear end 100b is provided with an attachment portion 133. Each attachment portion 133 extends from a rear end of the corresponding voltage detection probe pin 140. A voltage measurement terminal and/or a voltage wiring 261 are/is attached to each attachment portion 133. The front ends 100a are brought into contact with the terminals 35, 45 of the electricity storage device 1. Each probe pin may have any suitable shape. In one example, each probe pin may have an angular shape (such as a triangular shape, a pentagonal shape, or a hexagonal shape). In some embodiments, a lateral surface 110a of each probe pin 110 may be provided with a fin projecting along an outer circumference of the probe pin 110. In one example, such a fin may be provided instead of a projection 132 (which will be described below). Such a fin is able to dissipate heat, which is stored within each probe pin 110, into the air. In a preferred embodiment, such fins are provided at intervals along the lateral surface 110a of each probe pin 110. This enables efficient dissipation of heat stored within the probes 100 and the terminals 35, 45.

Each probe 100 is required to include at least one type of probe pin. Each probe pin is not limited to any particular type or use. Where appropriate, each probe pin may be replaced with another type of probe pin depending on a purpose of measurement. In one example, each probe pin 110 may include a voltage supply probe pin so as to be able to apply a voltage to the test object.

The front end 100a of each probe pin 110 according to this embodiment is flat. As illustrated in FIG. 4, the probes 100 in this embodiment are configured such that the flat front ends 100a of the probe pins 110 are brought into contact with the terminals 35, 45 of the electricity storage device 1. This contact brings the probe pins 110 into conduction with the electricity storage device 1, thus allowing, for example, a power source to supply an electric current, electric signal, or other signal to the electricity storage device 1. The probes 100 come into contact with the electricity storage device 1 through flat surfaces of the front ends 100a, which is preferable because a large contact area is secured between the electricity storage device 1 and each probe 100. When the electricity storage device 1 is a high-capacity (i.e., large-size) electricity storage device, a high electric current needs to be passed during evaluation test. In such a case, the terminals 35, 45 and the probe pins 110 are likely to rise in temperature. From the viewpoint of reducing such a temperature rise, the front end 100a of each probe pin 110 preferably has a large area (or in other words, a large contact area is preferably secured between the front end 100a of each probe pin 110 and the electricity storage device 1). For a stationary conduction current, the contact area to be secured may be 0.1 mm²/A or more, preferably 0.5 mm²/A or more, and more preferably 0.7 mm²/A or more. The front end 100a of each probe pin 110, however, does not necessarily have to be flat. In one example, the front end 100a of each probe pin 110 may be a probe needle (or may have a conical shape).

Each probe pin 110 may have any suitable length. Each probe pin 110 may have any suitable diameter. From the viewpoint of ensuring a sufficient contact area between the front end 100a of each probe pin 110 and the test object, the front end 100a of each probe pin 110 preferably has a large diameter. The front end 100a of each probe pin 110 may have a diameter of 3 mm or more, preferably has a diameter of 5 mm or more, and more preferably has a diameter of 10 mm or more. In this embodiment, each probe pin 110 has a length of about 50 mm to about 200 mm, inclusive. Each probe pin 110 has a circular columnar shape whose diameter is between about 2 mm and about 50 mm, inclusive.

Each probe pin 110 may have any suitable vertical cross-sectional area. Each probe pin 110 preferably has an area of 400 mm² or more in a vertical cross-section that passes through a central axis Ax, which extends in the longitudinal direction of the probe 100 (i.e., the up-down direction Y), and that faces a corresponding one of outlets 520 of the cooling mechanism 500. This results in an increase in pressure of cooling air to be received by each probe 100. Thus, effects of the cooling air are enhanced (or resulting cooling efficiency is enhanced), leading to a lower amount of heat generated by each probe 100. From the viewpoint of further reducing the amount of heat generated by each probe 100, the vertical cross-sectional area of each probe pin 110 is more preferably 500 mm² or more, and most preferably 600 mm² or more.

The probe pins 110 are electrically conductive. Any suitable material may be used for the probe pins 110 as long as it enables the probes 100 to achieve the effects of the techniques of the present disclosure. Examples of the material for the probe pins include metal. Typical examples of the material for the probe pins include silver, aluminum, gold, brass, copper, a copper alloy, zinc, a zinc alloy, nickel, palladium, a palladium alloy, and an alloy composed of any of these materials (e.g., a brass alloy). The probe pins may be made of any material other than those mentioned above. Alternatively, a coating may be applied to a surface of each probe pin. Typical examples of the coating include gold plating and nickel plating. From the viewpoint of durability, a nickel coating is preferably applied to the surface of each probe pin that is made of a copper alloy.

Each insulator 113 is provided so as to insulate the current supply probe pin 130 and the voltage detection probe pin 140 from each other. Any suitable material may be used for each insulator 113. Any material that is able to prevent direct electrical conduction between the current supply probe pin 130 and the voltage detection probe pin 140 may be used for each insulator 113. Examples of the material for each insulator 113 include an elastomer and plastic. Each insulator 113 may be hollow. From the viewpoint of enhancing durability to withstand a temperature rise of each probe 100 during measurement, each insulator 113 is preferably made of plastic.

### Bearing Portion 160

The probes 100 disclosed herein include the bearing portion 160. The bearing portion 160 includes through holes 162 (see FIG. 4) into each of which a corresponding one of the probe pins 110 is to be inserted. Each probe pin 110 that has been inserted into the corresponding through hole 162 is fixed to the bearing portion 160 with a disengagement stopper 161. In this embodiment, each disengagement stopper 161 is disposed adjacent to the rear end 100b of the corresponding probe pin 110 (i.e., between the bearing portion 160 and the rear end 100b). This makes it possible to prevent disengagement of each probe pin 110 toward its front end 100a.

The bearing portion 160 may be made of any suitable material. In this embodiment, the probe pins 110 are inserted into the through holes 162 of the bearing portion 160 made of metal. Although not illustrated in detail, an insulator may be provided between each probe pin 110 and the bearing portion 160. Examples of the material for the bearing portion may include a non-conductive material, such as plastic.

The bearing portion 160 fixes each probe pin 110 in orientation such that each probe 100 abuts against the electricity storage device 1. In this embodiment, the orientation of each probe pin 110 is fixed such that the longitudinal direction of each probe pin 110 is substantially perpendicular to an extension direction of the sealing plate 12 of the electricity storage device 1 (see FIG. 4). As used herein, the term “substantially perpendicular”, which indicates the orientation of each probe or each probe pin, is not limited to a strictly vertical direction but may refer to a direction inclined by a few or several degrees. Because what is required is to ensure conduction between each probe 100 and the test object, the longitudinal direction of each probe pin 110 may be inclined by, for example, up to a few degrees relative to the extension direction of the sealing plate 12 of the electricity storage device 1.

### Pressing Member 150

Each probe 100 includes pressing members 150. Each pressing member 150 presses the probe pin 110 such that the probe pin 110 comes into direct contact with the electricity storage device 1 (or more specifically, the positive terminal 35 or the negative terminal 45). In this embodiment, each probe 100 includes a first pressing member 151 to press the current supply probe pin 130 against the electricity storage device 1. Each probe 100 further includes a second pressing member 152 to press the voltage detection probe pin 140 against the electricity storage device 1. In this embodiment, the pressing members 150 (i.e., the first pressing members 151 and the second pressing members 152) are springs. Thus, a repulsive force is used to press the probe pins 110 against the test object. Each spring may exert any suitable repulsive force within a range that does not significantly impair the effects achieved by the techniques of the present disclosure. The repulsive force of each spring varies depending on, for example, a material used for each spring, allowing adjustment of a contact pressure exerted between each probe pin 110 and the test object. The pressing members 150, however, are not limited to this arrangement. Each pressing member may be, for example, a weight or rubber.

As illustrated in FIG. 6, each first pressing member 151 is disposed outside the corresponding current supply probe pin 130. Each first pressing member 151 is attached along the lateral surface 110a of the corresponding probe pin 110. Each first pressing member 151 includes a rear end 151b attached to a lower surface of the bearing portion 160. Each first pressing member 151 includes a front end 151a attached to the corresponding projection 132 such that the front end 151a presses the corresponding projection 132. The front end 100a of each probe pin 110 is brought into contact with the electricity storage device 1, which compresses each first pressing member 151, causing the front end 151a to push back the corresponding projection 132.

As illustrated in FIG. 6, each second pressing member 152 is disposed inside the corresponding current supply probe pin 130. Each second pressing member 152 includes a rear end 152b attached to a portion of the corresponding probe pin 110 located inside its rear end 100b. Each second pressing member 152 includes a front end 152a attached to a rear end 140b of the corresponding voltage detection probe pin 140 such that the front end 152a presses the rear end 140b of the corresponding voltage detection probe pin 140. The front end 100a of each probe pin 110 is pressed against the electricity storage device 1, which compresses each second pressing member 152, causing the corresponding voltage detection probe pin 140 to be pushed back against the electricity storage device 1.

The first and second pressing members 151 and 152 may exert any forces (e.g., any repulsive forces) that push the probe pins 110 against the test object, as long as they do not significantly impair the effects achieved by the techniques of the present disclosure. In this embodiment, the repulsive force of each second pressing member 152 is set lower than that of each first pressing member 151. As illustrated in FIG. 6, with each probe pin 110 not in abutment with the corresponding terminal of the electricity storage device 1, a front end 140a of the voltage detection probe pin 140 protrudes from a front end 130a of the current supply probe pin 130. Setting the repulsive force of each second pressing member 152 lower than that of each first pressing member 151 allows each voltage detection probe pin 140 to be quickly pushed into the hollow portion 131 of the corresponding current supply probe pin 130. The forces to be exerted by the first and second pressing members 151 and 152 to push the probe pins 110 against the test object, however, are not limited to those described above. The first and second pressing members 151 and 152 may exert similar forces that push the probe pins 110 against the test object.

### Cooling Mechanism 500

The cooling mechanism 500 generates cooling air to cool the terminals 35, 45 of the electricity storage device 1 and the probes 100. The cooling mechanism 500 is configured to cool heat-generating components (e.g., the probes 100 and the terminals 35, 45 of the electricity storage device 1). As illustrated in FIG. 2, the cooling mechanism 500 according to this embodiment is configured to blow cooling air onto the probes 100 connected to the terminals 35, 45 (or cause cooling air to flow along surfaces of the terminals 35, 45). The cooling mechanism 500 includes cooling fans 511, 512 to generate air. In this embodiment, the cooling fans 511, 512 include: a first cooling fan 511 configured to blow air onto the first probe 101; and a second cooling fan 512 configured to blow air onto the second probe 102. In the following description, when no distinction between the first cooling fan 511 and the second cooling fan 512 is necessary, the first cooling fan 511 and the second cooling fan 512 may simply be referred to as the “cooling fans 511, 512” for the sake of convenience. Air supply devices included in the cooling mechanism 500 are not limited to fans. Examples of the air supply devices may include compressors.

As illustrated in FIG. 3, each of the cooling fans 511, 512 is preferably provided such that its rotation axis RAX is perpendicular or substantially perpendicular to the lateral surface 110a of a corresponding one of the probes 100. Thus, cooling air supplied from the cooling mechanism 500 is directly blown onto the lateral surface 110a of each probe 100.

The cooling air supplied from the cooling mechanism 500 to the probes 100 may have any temperature within a range that does not significantly impair the effects achieved by the techniques of the present disclosure. The temperature of the cooling air is typically between about 4° C. and about 37° C. (or preferably between about 23° C. and about 27° C.). The cooling air whose temperature falls within this range enables more accurate temperature adjustment. Air supplied from the cooling mechanism 500 may be supplied as low-temperature cooling air by removing heat from the air with the use of a coolant, a heat exchanger, and/or other means when necessary.

The cooling mechanism 500 may be able to deliver cooling air at any airflow rate. However, as the deliverable airflow rate rises, the cooling efficiency increases accordingly. From the viewpoint of achieving more favorable cooling efficiency by delivering cooling air, a lower limit to the deliverable airflow rate is preferably 1 m³/min or more, more preferably 2 m³/min or more, and most preferably 3 m³/min or more. From the viewpoint of preventing application of an excessive load to the cooling mechanism 500, an upper limit to the deliverable airflow rate may be 10 m³/min or less, preferably 7 m³/min or less, and more preferably 5 m³/min or less.

As illustrated in FIG. 3, the cooling mechanism 500 according to this embodiment includes the outlets 520. Each outlet 520 is an opening facing the lateral surface of the corresponding probe 100. The cooling mechanism 500 further includes inlets 521. Each inlet 521 is an opening through which air is taken into the cooling mechanism 500. The outlets 520 and the inlets 521 are disposed opposite to each other, with the cooling fans 511, 512 interposed therebetween. The cooling fans 511, 512 draw outside air into the cooling mechanism 500 through the inlets 521. The cooling fans 511, 512 then discharge the drawn air out of the cooling mechanism 500 through the outlets 520. The outlets 520 may each have any suitable size. Typically, the cross-sectional area of each outlet 520 (i.e., the area of each opening through which air is to be blown out) may be larger than the vertical cross-sectional area of the corresponding probe pin 110. The inlets 521 may each have any suitable cross-sectional area. In some embodiments, each outlet may be provided such that its opening becomes smaller as it approaches the corresponding probe 100. In this case, the cross-sectional area of a portion of each outlet located adjacent to the corresponding probe 100 is smaller than the cross-sectional area of a portion of each outlet located adjacent to the corresponding one of the cooling fans 511, 512. This makes it possible to restrict a flow direction of cooling air and thus facilitates blowing the cooling air onto the heat-generating components, resulting in further enhanced cooling efficiency.

### Measurement Device 250

Any suitable measurement device may be used as long as it does not significantly impair the effects achieved by the techniques of the present disclosure. Although not illustrated in detail, a measurement device 250 in this embodiment includes a current generation section 251, a voltage measurement section 253, a temperature measurement section 254, and the controller 270. The current generation section 251 is a device to supply an electric current or electric signal to the electricity storage device 1 through the probe(s) 100. In other words, the current generation section 251 is able to function as a power supply. The voltage measurement section 253 is a device to measure a voltage of the electricity storage device 1. Where appropriate, any suitable device(s) may be used in accordance with a purpose of electricity storage device evaluation. Examples of the measurement device include an oscilloscope, a charging and discharging device, and a tester. The temperature measurement section 254 is a device to measure a temperature of the object based on signals received from temperature measurement terminals (i.e., a thermocouple 262). The controller 270 is configured or programmed to control the airflow rate of the cooling fans 511, 512 based on the temperature measured by the temperature measurement section 254.

As illustrated in FIG. 4, the probe unit 200 includes: the first probe 101 to be connected to the positive terminal 35 of the electricity storage device 1; and the second probe 102 to be connected to the negative terminal 45 of the electricity storage device 1. The first and second probes 101 and 102 are similar in configuration to the probes 100 described above. In this embodiment, the bearing portion 160 is a plate-shaped member that extends in the lengthwise direction of the sealing plate 12 of the electricity storage device 1. The bearing portion 160 is provided with the through holes 162, the number of which is two. The first probe 101 is inserted into one of the through holes 162, and the second probe 102 is inserted into the other through hole 162. The through holes 162 are provided such that one of the through holes 162 faces the positive terminal 35 and the other through hole 162 faces the negative terminal 45. The first and second probes 101 and 102 share the bearing portion 160. The probe pin 110 of the first probe 101 is inserted into the through hole 162 that faces the positive terminal 35. The probe pin 110 of the second probe 102 is inserted into the through hole 162 that faces the negative terminal 45. The bearing portion 160, however, may have any suitable shape other than that described above.

As illustrated in FIG. 4, the evaluation apparatus 300 in this embodiment includes a pair of holding plates 210a1 and 210a2 between which the electricity storage device 1 is to be sandwiched in its thickness direction (i.e., the front-rear direction Z). The pair of holding plates 210a1 and 210a2 abut against the wide surfaces 11b1 and 11b2 of the electricity storage device 1. The pair of holding plates 210a1 and 210a2 are larger than the wide surfaces 11b1 and 11b2 against which the holding plates 210a1 and 210a2 abut. The pair of holding plates 210a1 and 210a2 are provided with through holes 214 into each of which a bolt 212 is to be inserted. As illustrated in FIG. 4, each bolt 212 is inserted into corresponding ones of the through holes 214 of the pair of holding plates 210a1 and 210a2, and each bolt 212 and an associated nut 213 are tightened together, thereby fixing the electricity storage device 1 between the holding plates 210a1 and 210a2. Through the bolts 212, supporting members 513 for attachment of the cooling fans 511, 512 are also fixed to the pair of holding plates 210a1 and 210a2. The pair of holding plates 210a1 and 210a2 include protrusions 211 to restrain the probe unit 200. The protrusions 211 hold the bearing portion 160 of the probe unit 200 therebetween, thus securing the probe unit 200. Any suitable material may be used for the holding plates 210a1 and 210a2. The holding plates 210a1 and 210a2 are preferably made of a high-strength material. In this embodiment, the holding plates 210a1 and 210a2 made of metal (e.g., a stainless alloy) are used. The cooling mechanism 500 is fixed to the pair of holding plates 210a1 and 210a2 through the supporting members 513. The cooling mechanism 500 is disposed to face the lateral surfaces 110a of the probes 100 so as to be able to blow cooling air onto the probes 100. As illustrated in FIG. 3, the cooling fans 511, 512 in this embodiment are disposed such that the outlets 520 face the lateral surfaces 110a of the probes 100. The cooling mechanism 500 is disposed such that the central axis AX of each probe 100 and the rotation axis RAX of the corresponding one of the cooling fans 511, 512 are perpendicular to each other. The central axis AX of each probe 100 and the rotation axis RAX of the corresponding one of the cooling fans 511, 512, however, do not necessarily have to be perpendicular to each other. Each outlet 520 may be adjusted in orientation within a range that does not impair the effects achieved by the techniques of the present disclosure. Each outlet 520 may be spaced at any suitable distance from the lateral surface 110a of the corresponding probe 100. From the viewpoint of allowing the cooling mechanism 500 to efficiently blow air onto the lateral surface 110a of each probe 100, the distance is preferably 100 mm or less and more preferably 50 mm or less.

In this embodiment, a first L-shaped metal fitting 201 is attached adjacent to the rear end 100b of the first probe 101. A second L-shaped metal fitting 202 is attached adjacent to the rear end 100b of the second probe 102. As illustrated in FIG. 4, the first and second L-shaped metal fittings 201 and 202 are provided with through holes 203 for attachment of the probe pins 110. The first and second L-shaped metal fittings 201 and 202 are electrically conductive members. The probe pins 110 are passed through the through holes 203 of the first and second L-shaped metal fittings 201 and 202 and attached thereto such that the probe pins 110 are in contact with inner peripheries of the through holes 203. This enables conduction between the probe pins 110 and the electricity storage device 1. The first and second L-shaped metal fittings 201 and 202 are provided with attachment holes 204 for attachment of current wirings 260a and 260b. As illustrated in FIG. 2, the current wirings 260a and 260b are each connected a corresponding one of the attachment holes 204. A first wire of the current wiring 260a connects the current generation section 251 to the first probe 101. A second wire of the current wiring 260b connects the current generation section 251 to the second probe 102. Thus, charging and discharging currents are supplied to the electricity storage device 1 through the first and second probes 101 and 102. The voltage wiring 261 is attached to each attachment portion 133. The voltage wiring 261 is connected to the voltage measurement section 253. An airflow rate adjustment wiring 263 connects the controller 270 to the cooling fans 511, 512. The thermocouple 262 is directly attached to the positive and negative terminals 35 and 45 of the electricity storage device 1 by using fasteners (not illustrated). The thermocouple 262 is connected to the temperature measurement section 254. The thermocouple does not necessarily have to be used for temperature measurement. Any suitable temperature sensor known in the art may be used for temperature measurement. In one example, a sensor, such as an infrared sensor, that does not come into direct contact with a measurement object may be used for temperature measurement.

### Electricity Storage Device Evaluation Method

The following description discusses a method for evaluating the electricity storage device 1 using the evaluation apparatus 300 described above. FIG. 7 is a flow chart of an electricity storage device evaluation method that uses the electricity storage device evaluation apparatus disclosed herein. The electricity storage device evaluation method disclosed herein includes: bringing the probes 100 into abutment with the terminals 35, 45 of the electricity storage device 1 and placing the cooling mechanism 500 such that cooling air is blown onto the probes 100 (step S01); supplying a predetermined electric current or voltage to the electricity storage device 1 so as to charge or discharge the electricity storage device 1 (step S02); measuring a temperature T of the terminals 35, 45 of the electricity storage device 1 during charging or discharging (step S03); calculating a temperature increase ΔTtemperature increase of the terminals 35, 45 based on a temporal change in the measured temperature T of the terminals 35, 45 (step S04); and changing an airflow rate Q of cooling air in response to the calculated temperature increase ΔT (step S05). Steps S01 to S05 are preferably performed in this order as illustrated in FIG. 7. The following description, however, is not intended to limit the electricity storage device evaluation method to the flow chart illustrated in FIG. 7. In one example, any of steps S01 to S05 may include one or more additional processes. Typically, steps S04 and S05 may be performed by the controller 270 of the evaluation apparatus 300.

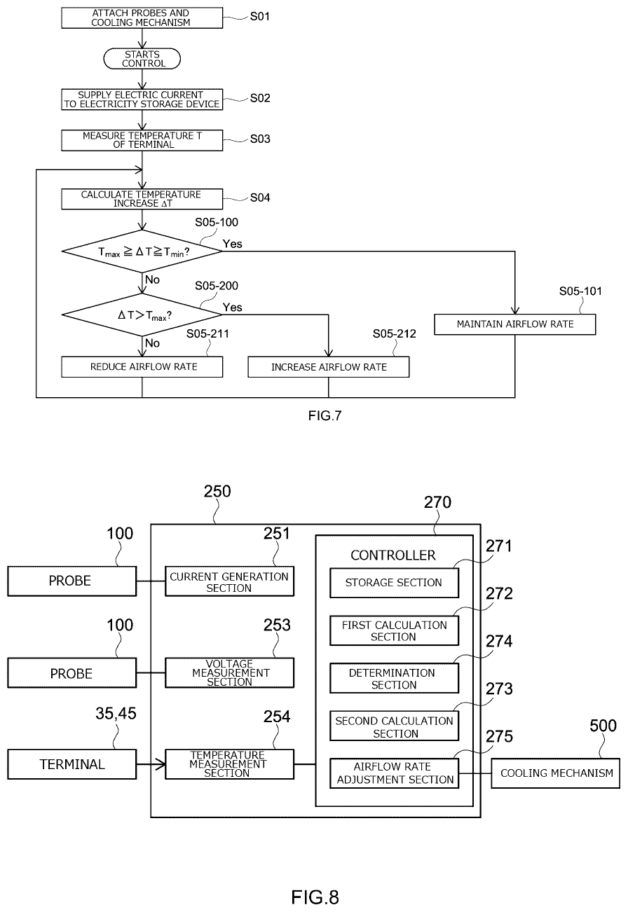

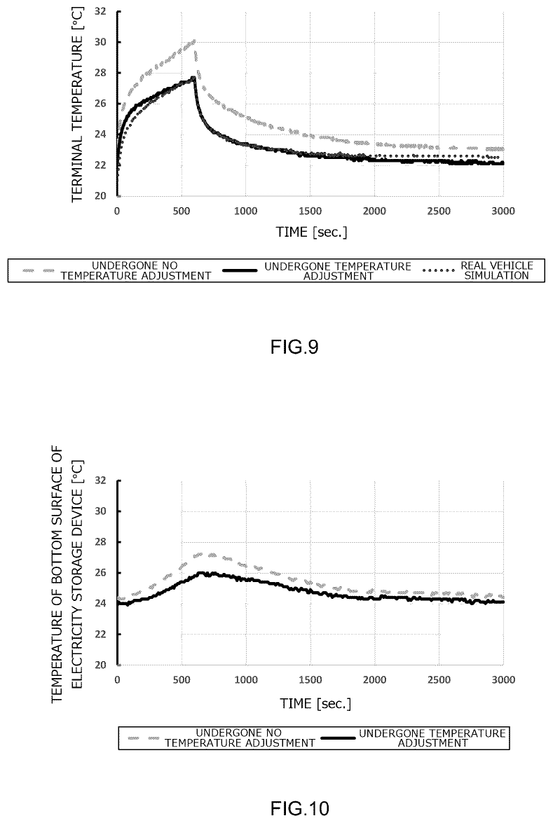

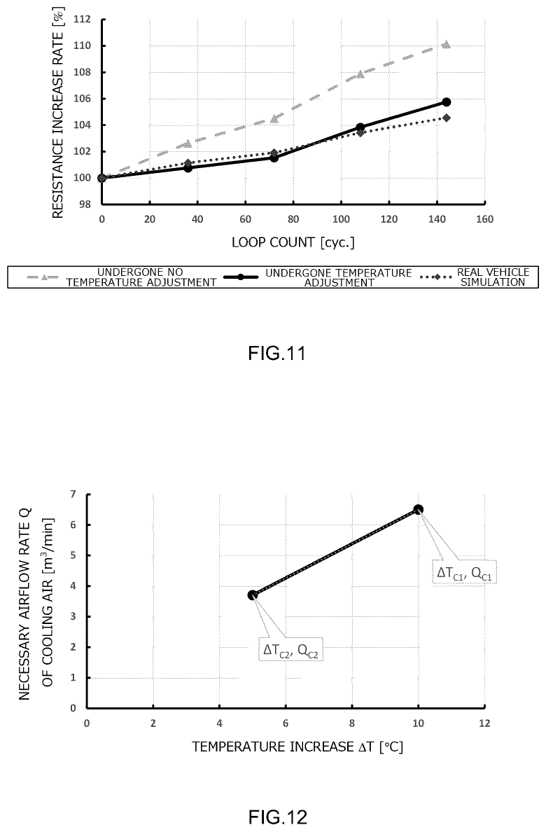

FIG. 8 is a functional block diagram of an electricity storage device evaluation apparatus according to one aspect disclosed herein. FIG. 9 is a graph illustrating changes in terminal temperature of the electricity storage device in the 1st cycle. In FIG. 9, the vertical axis represents terminal temperature (C°), and the horizontal axis represents time(s). FIG. 10 is a graph illustrating changes in temperature of a bottom surface of the electricity storage device in the 1st cycle. In FIG. 10, the vertical axis represents the temperature (C.°) of a bottom surface 11a of the electricity storage device, and the horizontal axis represents time (sec.). FIG. 10 indicates temperature measurements obtained by bringing a thermocouple into direct contact with the bottom surface 11a of the electricity storage device 1. FIG. 11 is a graph illustrating changes in resistance increase rate of the electricity storage device during charging and discharging test. In FIG. 11, the vertical axis represents the resistance increase rate (%) of the electricity storage device, and the horizontal axis represents a cycle frequency or the number of cycles performed (cyc.). FIG. 12 is a graph illustrating a relationship between an increase in terminal temperature of the electricity storage device and an airflow rate of cooling air. In FIGS. 9 to 11, solid lines indicate temperature changes or resistance increase rate of the electricity storage device measured by the evaluation apparatus 300 according to this embodiment, broken lines indicate temperature changes or resistance increase rate measured by the evaluation apparatus 300 during deactivation of the cooling mechanism 500, and dotted lines indicate temperature changes or resistance increase rate during real vehicle simulation.

A preferred aspect of the electricity storage device evaluation method disclosed herein involves performing feedback control to change the airflow rate of cooling air such that the temperature increase ΔT approximates that observed in a previously obtained temperature change model. When such feedback control is performed, the airflow rate of cooling air is increased and/or reduced such that the temperature increase ΔT falls within an allowable temperature range (Tₘᵢₙ to Tₘₐₓ) set based on the previously obtained temperature change model.

### Temperature Change Model

The previously obtained temperature change model may be generated using, for example, a real vehicle simulation that simulates temperature changes of an electricity storage device installed on a vehicle. Examples of test conditions for the real vehicle simulation include those given in Table 1 below. The real vehicle simulation involves performing constant-current charging of the electricity storage device at a constant current of 1 C for 600 seconds. The real vehicle simulation then involves performing constant-current discharging of the electricity storage device at a constant current of 0.25 C for 2400 seconds. This constant-current charging and discharging process is defined as one cycle and is repeated for 144 cycles. In the real vehicle simulation, the electricity storage device is evaluated, with front ends of probes and terminals of the electricity storage device welded to each other.

TABLE 1

| | Current | Time | |
|---|---|---|---|
| Mode | [C] | [s] | Loop Count |
| Constant-Current Charging | 1 | 600 | 144 |
| Constant-Current Discharging | 0.25 | 2400 | 144 |

Alternatively, the temperature change model may be generated by actually installing the electricity storage device 1 on a vehicle and using values indicative of measured temperature changes. In other words, any temperature change model may be used. Suitable modifications and/or settings may be made to the temperature change model in accordance with the type and/or purpose of the electricity storage device.

### Decision of Airflow Rate of Cooling Air

One preferred aspect of the electricity storage device evaluation method disclosed herein may involve deciding the airflow rate of cooling air necessary to cool the probes 100. FIG. 12 is a graph illustrating a relationship between the temperature increase ΔT of the terminals 35, 45 of the electricity storage device 1 and the airflow rate Q of cooling air. The following description discusses an exemplary process of generating the graph illustrated in FIG. 12. First, the process involves measuring terminal temperatures when an electricity storage device evaluation test that entails a real vehicle simulation is conducted under the conditions given in Table 1. The process involves calculating, from the measured temperatures, a temperature increase ΔTₘ relevant to the real vehicle simulation. The process then involves measuring a temperature increase ΔT_{c1} when the electricity storage device 1 according to this embodiment is subjected to one cycle of charging and discharging under the conditions given in Table 1. The process involves activating the cooling mechanism 500 in measuring the temperature increase ΔT_{c1}, and deciding an airflow rate Q_{c1} of cooling air such that the temperature increase ΔT_{c1} falls within the allowable temperature range (Tₘᵢₙ to Tₘₐₓ), i.e., within a tolerance of ±1° C., for the previously measured temperature increase ΔTₘ. The process also involves performing these steps under conditions different from those given in Table 1. Specifically, the process involves measuring a temperature increase ΔT_{c2} when the electricity storage device 1 according to this embodiment is charged and discharged under conditions given in Table 2. The process involves activating the cooling mechanism 500 in measuring the temperature increase ΔT_{c2}, and deciding an airflow rate Q_{c2} of cooling air such that the temperature increase ΔT_{c2} falls within the allowable temperature range (Tₘᵢₙ to Tₘₐₓ), i.e., within a tolerance of ±1° C., for the previously measured temperature increase ΔTₘ. The above-described process is able to generate the graph indicating the relationship between the temperature increase ΔT and the airflow rate Q of cooling air as illustrated in FIG. 12.

TABLE 2

| | Current | Time |
|---|---|---|
| Mode | [C] | [s] |
| Constant-Current Charging | 0.5 | 900 |
| Constant-Current Discharging | 1.5 | 300 |

The allowable temperature range (Tₘᵢₙ to Tₘₐₓ) is decided based on the previously obtained temperature change model. A person skilled in the art may set any suitable values as the upper limit Tₘₐₓ and the lower limit Tₘᵢₙ of the allowable temperature range by, for example, preliminarily conducting an evaluation test in accordance with the temperature change model. Typically, a temperature range of ±1° C. may be set for temperatures in the previously obtained temperature change model. In this embodiment, the upper limit Tₘₐₓ and the lower limit Tₘᵢₙ in the real vehicle simulation are decided based on actual measurement values indicative of previously measured temperatures of the terminals 35, 45 in the real vehicle simulation. With respect to the actual measurement values, the upper limit Tₘₐₓ is decided to be +1° C. and the lower limit Tₘᵢₙ is decided to be −1° C. The set temperature range may be stored in a storage section 271. Some aspects of the electricity storage device evaluation method disclosed herein may include deciding the allowable temperature range based on the previously obtained temperature change model.

### Step S01

Referring now to FIG. 7, a preferred example of an electricity storage device evaluation method disclosed herein will be described in detail below. In step S01, the probes 100 are brought into abutment with the terminals 35, 45 of the electricity storage device 1, and the cooling mechanism 500 is placed such that cooling air is blown onto the probes 100. First, the electricity storage device 1 serving as an evaluation object is prepared. The electricity storage device to be evaluated may be of any type. A typical evaluation object in this example is the electricity storage device 1 including the terminals 35, 45 at its upper surface (which is defined by the sealing plate 12) as illustrated in FIG. 4. The probe unit 200 is disposed on an upper portion of the prepared electricity storage device 1. The first probe 101 is brought into abutment with the positive terminal 35. The second probe 102 is brought into abutment with the negative terminal 45. The cooling mechanism 500 is mounted such that the outlets 520 face the lateral surfaces 110a of the probes 100. Thus, cooling air generated by the cooling fans 511, 512 is directly blown onto the lateral surfaces 110a of the probes 100.

### Step S02

In step S02, the electricity storage device 1 is charged or discharged by supplying a predetermined electric current or voltage to the electricity storage device 1. In this embodiment, the current generation section 251 of the measurement device 250 supplies a charging or discharging current to the first probe 101 or the second probe 102 through the current wiring 260a or 260b.

In one example of a charging method, the electricity storage device 1 is charged at constant current until a predetermined charging time (typically between 10 seconds and 5400 seconds) elapses. In another example, the electricity storage device 1 is charged at constant current until a predetermined voltage (e.g., a voltage of between about 3.5 V and about 4.5 V) is reached. The charging method may involve performing constant-current/constant-voltage charging using these examples in combination. In one example of a discharging method, the electricity storage device 1 is discharged at constant current until a predetermined discharging time (typically between 10 seconds and 5400 seconds) elapses. In another example, the electricity storage device 1 may be discharged at constant current until a predetermined voltage (e.g., a voltage of between about 2.5 V and about 3.5 V) is reached. The discharging method may involve performing constant-current/constant-voltage discharging using these examples in combination. In this embodiment, the electric current supplied from the current generation section 251 is passed to the second probe 102 connected to the negative terminal 45 of the electricity storage device 1, thus charging the electricity storage device 1. The electric current supplied from the current generation section 251 is passed to the first probe 101 connected to the positive terminal 35 of the electricity storage device 1, thus discharging electric charges from the electricity storage device 1.

In step S02, any type and magnitude (or amount) of electric current, electric signal, or other signal may be supplied to the electricity storage device 1. The type and magnitude of electric current, electric signal, or other signal to be supplied may be suitably selected in accordance with the evaluation object and a purpose of testing. For example, when a charging and discharging test is conducted on a large-size electricity storage device installable on a vehicle or other transport means (a typical example of which is an electricity storage device with a capacity of 50 Ah or more), step S02 preferably involves passage of a high electric current. An electric current of any suitable magnitude may be passed during charging and discharging test. During charging, the electricity storage device is preferably charged at a constant current of 20 A/s or more, more preferably charged at a constant current of 50 A/s or more, and most preferably charged at a constant current of 100 A/s or more. During discharging, the electricity storage device is preferably discharged at a constant current of 20 A/s or more, more preferably discharged at a constant current of 50 A/s or more, and most preferably discharged at a constant current of 100 A/s or more.

Some embodiments may include measuring an electric characteristic or other characteristic of the electricity storage device based on an electric signal or other signal received from the evaluation object. The evaluation apparatus 300 according to this embodiment is able to supply an electric current to the electricity storage device 1 through the current supply probe pin 130 of each probe 100 and to measure a voltage of the electricity storage device 1 through the voltage detection probe pin 140 of each probe 100. An electric signal from each voltage detection probe pin 140 is sent to the voltage measurement section 253 through the voltage wiring 261. A resistance value between each probe 100 and the electricity storage device 1 is measured based on a value of electric current supplied through the current supply probe pin 130 and a value of voltage measured using the voltage detection probe pin 140.

Exemplary electric characteristic measurement in this embodiment involves connecting the first probe 101 to the positive terminal 35. During discharging, an electric current is supplied from the current generation section 251 to the first probe 101, thus discharging the electricity storage device 1. A voltage at the positive terminal 35 in this case is measured by the voltage measurement section 253 through the voltage detection probe pin 140 of the first probe 101. Thus, a voltage during discharging is measurable. The second probe 102 is connected to the negative terminal 45. During charging, an electric current is supplied from the current generation section 251 to the second probe 102, thus charging the electricity storage device 1. A voltage at the negative terminal 45 in this case is measured by the voltage measurement section 253 through the voltage detection probe pin 140 of the second probe 102. Thus, a voltage during charging is measurable. In addition, a voltage between the positive and negative terminals 35 and 45 of the electricity storage device 1 is measurable using the first and second probes 101 and 102. As a result, resistance between the positive and negative terminals 35 and 45 of the electricity storage device 1 is determinable.

One example of electric characteristic measurement involves measuring (or recording), at predetermined recording intervals, voltage variations with respect to the charging time or discharging time described above. The recording intervals are preferably 0.1 sec or less (i.e., 100 msec or less). The voltage variations are recorded in a manner that includes a discharging period used for resistance calculation. The voltage variations may be recorded immediately after start of discharging. Alternatively, settings may be made such that recording starts after lapse of a predetermined time from the start of discharging. Measuring or recording the voltage variations in the above-described manner provides a chart in which the voltage variations are plotted with respect to the discharging time.

Some embodiments include calculating a measurement result (e.g., a resistance value) from electric signals or other signals received from the electricity storage device 1. In one example, from a discharging current value during discharging and a voltage drop value during the set discharging period, a resistance value of the electricity storage device 1 during the predetermined discharging period is calculable in accordance with Ohm's law (V=IR, where V represents voltage, I represents electric current, and R represents resistance).

### Step S03

In step S03, the temperature of at least one of the positive and negative terminals 35 and 45 of the electricity storage device 1 during charging or discharging is measured. The evaluation apparatus 300 according to this embodiment is configured such that a temperature of the terminals 35, 45 is detected by the thermocouple 262 attached to the external terminal conductive members 36 and 46 and is thus measured by the temperature measurement section 254. An average of the measured temperatures of the positive terminal 35 (or the positive electrode external terminal conductive member 36) and the negative terminal 45 (or the negative electrode external terminal conductive member 46) is determined to be the temperature of the terminals 35 and 45. The average of the temperatures of the positive and negative terminals, however, does not necessarily have to be used as the terminal temperature. A person skilled in the art may suitably decide which of the temperature of the positive terminal, the temperature of the negative terminal, and the average of the temperatures of the positive and negative terminals is to be used in consideration of heat generation behaviors of the positive and negative electrodes.

The temperature of the terminals 35, 45 may be measured or recorded at any intervals within a range that does not significantly impair the effects achieved by the techniques of the present disclosure. In one example, the temperature recording intervals are preferably 0.1 sec or less (i.e., 100 msec or less). Typically, settings may be made such that temperature recording starts immediately after start of evaluation (e.g., a charging and discharging test) of the electricity storage device 1 or after lapse of a predetermined time from the start of evaluation.

### Step S04

In step S04, the temperature increase ΔT of the terminals 35 and 45 is calculated based on a temporal change in the measured temperature of the terminals 35 and 45. In this embodiment, a first calculation section 272 calculates the temperature increase ΔT based on temperatures T₀ and Tₜ measured by the temperature measurement section 254 during evaluation of the electricity storage device 1.

The first calculation section 272 calculates the temperature increase ΔT that is a variation in the temperature of the terminals 35, 45 between a preset time to and a preset time tₜ. The times t₀ and tₜ may be suitably preset in accordance with the type of the electricity storage device and/or a purpose of evaluation. First, the first calculation section 272 receives a temperature value at the time t₀, which is selected from among temperature values of the terminals 35, 45 measured by the temperature measurement section 254. The first calculation section 272 determines the temperature value at the time t₀ to be the temperature T₀. The first calculation section 272 subsequently receives a temperature value at the time tₜ, which is selected from among the temperature values of the terminals 35, 45 measured by the temperature measurement section 254. The first calculation section 272 determines the temperature value at the time tₜ to be the temperature Tₜ. In this embodiment, the first calculation section 272 calculates the temperatures T₀ and Tₜ based on averages of the temperatures of the positive and negative terminals 35 and 45. In this case, the first calculation section 272 may receive the temperatures of the positive and negative terminals 35 and 45 at the times t₀ and tₜ, calculate an average of the temperatures at the time to and an average of the temperatures at the time tₜ, and determine the calculated average temperatures to be the temperatures T₀ and Tₜ.

The first calculation section 272 calculates the temperature increase ΔT of the terminals 35 and 45 using the temperatures T₀ and Tₜ. More specifically, the first calculation section 272 calculates the temperature increase ΔT using the following equation (1): ΔT=(Tₜ−T₀)/(tₜ−t₀), where ΔT represents the temperature increase, Tₜ represents the temperature of the terminals 35 and 45 at the time tₜ, and T₀ represents the temperature of the terminals 35 and 45 at the time to.

The times t₀ and tₜ may each be any time between the start and end of the test. In this embodiment, the time to is when the temperature T₀ at the start of the test is measured. The time tₜ is when the temperature Tₜ at an airflow rate control timing is measured. The time t₀, however, is not required to coincide with the start of the test. In other words, the temperature T₀ is not required to be the temperature of the terminals 35, 45 at the start of the test. The time to does not necessarily have to coincide with the start of the test but may be any time preceding the time tₜ. The time tₜ does not necessarily have to coincide with the control timing. In other words, the temperature Tₜ does not necessarily have to be the temperature of the terminals 35, 45 at the predetermined control timing. The time tₜ may be any time as long as it does not significantly impair the effects achieved by the techniques of the present disclosure.

### Step S05

In step S05, the airflow rate of cooling air is changed in response to the temperature increase ΔT. In one example, step S05 includes step S05-100 and step S05-200. Step S05-100 involves determining whether the temperature increase ΔT falls within the allowable temperature range (Tₘᵢₙ to Tₘₐₓ). Step S05-200 involves determining whether the temperature increase ΔT is above the upper limit Tₘₐₓ of the allowable temperature range.

A determination section 274 receives the temperature increase ΔT calculated by the first calculation section 272 in step S04. The determination section 274 determines whether the temperature increase ΔT falls within the allowable temperature range (Tₘᵢₙ to Tₘₐₓ) in accordance with the previously obtained temperature change model (step S05-100). This determination is made using the temperature range (Tₘᵢₙ to Tₘₐₓ) stored in the storage section 271.

Upon determination that the temperature increase ΔT falls within the allowable temperature range, the determination section 274 instructs an airflow rate adjustment section 275 to maintain the airflow rate of cooling air (S05-101). Alternatively, the determination section 274 may determine that there is no need to change the airflow rate of cooling air, which ends the determination process performed by the determination section 274. Thus, the airflow rate of cooling air is maintained until the next control timing comes.

Upon determination that the temperature increase ΔT falls outside the allowable temperature range, the determination section 274 instructs the airflow rate adjustment section 275 to change the airflow rate of cooling air such that the temperature increase ΔT falls within the allowable temperature range. More specifically, the determination section 274 first determines whether the temperature increase ΔT is above the upper limit Tₘₐₓ of the allowable temperature range (step S05-200). When the temperature increase ΔT is not above the upper limit Tₘₐₓ (which in this case means that the temperature increase ΔTis below the lower limit Tₘᵢₙ of the allowable temperature range), the determination section 274 instructs the airflow rate adjustment section 275 to reduce the airflow rate of cooling air (step S05-211). When the temperature increase ΔT is above the upper limit Tₘₐₓ, the determination section 274 instructs the airflow rate adjustment section 275 to increase the airflow rate of cooling air (step S05-212).

In one preferred aspect of the electricity storage device evaluation method disclosed herein, upon being instructed to increase or reduce the airflow rate of cooling air by the determination section 274, the airflow rate adjustment section 275 adjusts the airflow rate based on the airflow rate Q (m³/min) of cooling air outputted from a second calculation section 273. In some embodiments, the airflow rate adjustment section 275 may adjust the airflow rate of cooling air to 0 m³/min (or may deactivate the cooling fans 511, 512) upon being instructed to reduce the airflow rate of cooling air.

Upon determining that the temperature increase ΔT falls outside the allowable temperature range (Tₘᵢₙ to Tₘₐₓ) in accordance with the previously obtained temperature change model, the determination section 274 instructs the second calculation section 273 to calculate the airflow rate Q of cooling air. In this embodiment, the second calculation section 273 calculates the airflow rate Q of cooling air using the following equation (2): Q=ΔTA+B, where ΔT represents the temperature increase of the terminals 35, 45, A represents a necessary airflow rate sensitivity for a temperature rise, and B represents a necessary airflow rate for a steady state. Specifically, the second calculation section 273 outputs the airflow rate Q of cooling air upon receiving input of: the value A of the necessary airflow rate sensitivity for a temperature rise in a measurement environment (e.g., an environment with a temperature of about 25° C.); the value B of the necessary airflow rate for the steady state; and the measured temperature increase ΔT of the terminals 35, 45. The equation (2) may be formulated by execution of a preliminary test or other test in advance by a person skilled in the art as illustrated in FIG. 12. In this embodiment, the equation (2) is a linear approximate equation obtained by linearly approximating the airflow rates Q_{c1} and Q_{c2} of cooling air for the temperature increases ΔT_{c1} and ΔT_{c2} illustrated in FIG. 12. As illustrated in FIG. 12, the airflow rate Q of cooling air necessary to approximate the previously obtained temperature change model increases in proportion to the value of the temperature increase ΔT.

The predetermined airflow rate Q of cooling air in this embodiment is calculable based on the number of revolutions per minute (rpm) of the cooling fans 511, 512. A relationship between the number of revolutions of the cooling fans 511, 512 and the airflow rate Q of cooling air may be suitably decided in consideration of diameters and/or other dimensions of the cooling fans to be used.

The second calculation section 273 receives the temperature increase ΔT calculated by the first calculation section 272. Upon receiving input of the temperature increase ΔT from the first calculation section 272, the second calculation section 273 calculates the airflow rate Q of cooling air using the equation (2). The second calculation section 273 outputs the calculated airflow rate Q to the airflow rate adjustment section 275.

The airflow rate adjustment section 275 outputs the airflow rate Q, which has been received from the second calculation section 273, to the cooling mechanism 500. In this embodiment, the number of revolutions of the cooling fans 511, 512 is increased in response to a control signal outputted from the airflow rate adjustment section 275, with the result that the cooling mechanism 500 adjusts the temperature of the terminals 35, 45. Alternatively, the first cooling fan 511 to cool the positive terminal 35 and the second cooling fan 512 to cool the negative terminal 45 may be controlled in response to different control signals.

### Control Timing

The airflow rate of cooling air is adjustable at each predetermined control timing. The control timing may be any timing as long as it does not significantly impair the effects achieved by the techniques of the present disclosure. Typically, the airflow rate Q of cooling air is adjusted by outputting the temperature increase ΔT every ten seconds (preferably every five seconds, and more preferably every one second). In some embodiments, when the temperature increase ΔT exceeds the allowable temperature range by a few° C. (e.g., by 5° C. or more), the determination section 274 instructs the airflow rate adjustment section 275 to adjust the airflow rate Q of cooling air immediately (e.g., within 0.1 to 0.9 seconds). Thus, if an observed temperature behavior deviates from that in the previously obtained temperature change model during evaluation test, the necessary airflow rate would be outputted immediately such that the temperature increase ΔT falls within the allowable temperature range.

For example, after being manufactured or before being put to use, an electricity storage device usually undergoes an evaluation test so as to have its electric characteristics evaluated. Such an evaluation test involves connection of probes to terminal surfaces of an electricity storage device and passage of an electric current, electric signal, or other signal to the electricity storage device. The electric characteristics of the electricity storage device are evaluated by measuring a voltage, an electric signal, or other signal outputted from the electricity storage device. For example, an evaluation test such as a real vehicle simulation involves welding probes to terminals of an electricity storage device serving as an evaluation object.

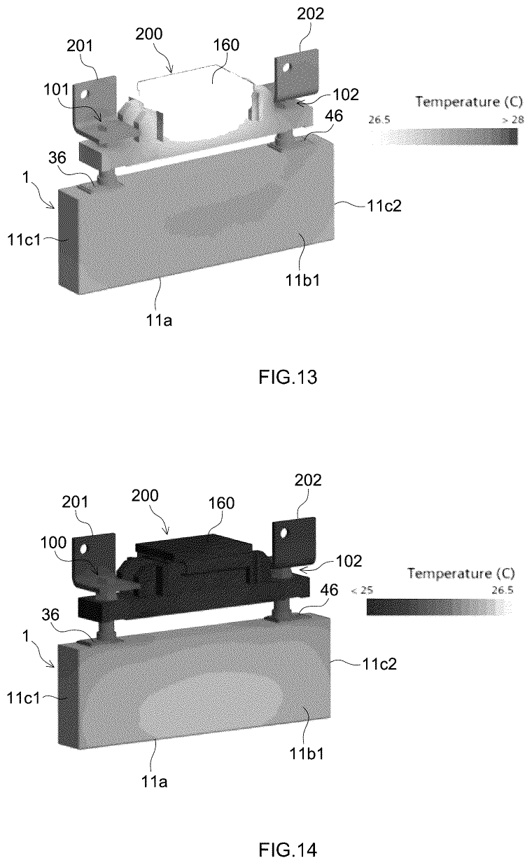

When an electric signal or other signal is passed to an electricity storage device, with its terminals merely in contact with probes without being welded thereto, the electricity storage device generates heat owing to a rise in resistance at terminal interface. This may cause the electricity storage device to enter a high temperature state that is beyond what is expected in a temperature change model used, for example, in a real vehicle simulation, resulting in a failure to perform an accurate evaluation. FIG. 13 is a temperature contour diagram generated from CAE (computer-aided engineering) analysis conducted on the electricity storage device 1 that has not undergone temperature adjustment by a cooling mechanism. The terminals 35, 45 of the electricity storage device 1 illustrated in FIG. 13 are not welded to the probes 100. FIG. 13 illustrates a temperature state of the electricity storage device 1 after lapse of 3000 seconds from constant-current charging and discharging in the first cycle of a charging and discharging test, which is performed under the test conditions given in Table 1. As illustrated in FIG. 13, the amount of heat generated by the terminals 35, 45 and the probes 100 is increased to the highest level. As illustrated in FIG. 9, during constant-current charging, the electricity storage device that has not undergone temperature adjustment by the cooling mechanism (which is indicated by the broken line in FIG. 9) exhibits a greater temperature increase than the electricity storage device that has undergone temperature adjustment by the cooling mechanism (which is indicated by the solid line in FIG. 9). Such an increase in heat generation amount may cause, for example, a rise in temperature of the entire electricity storage device and/or degradation of the electricity storage device. As illustrated in FIG. 13, a portion of the probe unit 200 that supports the bearing portion 160 is located relatively away from the electricity storage device 1 and thus has a temperature of 26.5° C. or less.

As indicated by the dotted line in FIG. 9, an evaluation test that entails a real vehicle simulation involving welding the probes to the terminals results in a relatively small temperature increase during constant-current charging. As illustrated in FIG. 11, during charging and discharging test, the resistance increase rate of the electricity storage device that has not undergone temperature adjustment by the cooling mechanism is higher than that observed in the real vehicle simulation. This may end in a failure to accurately evaluate the electricity storage device. The evaluation test that entails the real vehicle simulation requires additional steps, such as welding the probes to the terminals and performing a disassembling process after the evaluation test, which unfortunately results in an increase in the number of steps.

The electricity storage device evaluation apparatus 300 according to the above-described embodiment includes the electrically conductive probes 100, the cooling mechanism 500, and the controller 270. The probes 100 are attached to the electricity storage device 1 such that the probes 100 abut against the terminals 35, 45 exposed outside the electricity storage device 1. The cooling mechanism 500 is configured to supply cooling air to the probes 100, with the probes 100 being attached to the terminals 35 and 45. The controller 270 detects the temperature of the terminals 35, 45. The controller 270 is configured or programmed to adjust the airflow rate of cooling air based on the detected temperature of the terminals 35, 45. The probes 100 of the electricity storage device evaluation apparatus 300 are not welded to the terminals 35 and 45. This results in a reduction in the number of steps because the evaluation apparatus 300 does not require welding and disassembling process. The evaluation apparatus 300 is configured such that cooling air is blown onto the probes 100 and the surfaces of the terminals 35, 45, which generate a high amount of heat, during evaluation test of the electricity storage device 1. Consequently, the evaluation apparatus 300 is able to efficiently cool the electricity storage device 1 by cooling portions of the electricity storage device 1 that generate a high amount of heat.

FIG. 14 is a temperature contour diagram generated from CAE analysis conducted on the electricity storage device 1 that has undergone temperature adjustment by the cooling mechanism 500. As is clear from FIG. 14, the temperature of the entire electricity storage device 1 decreases as a result of cooling the probes 100. As illustrated in FIG. 10, the temperature of the bottom surface 11a of the electricity storage device 1 is lower when subjected to temperature adjustment by the cooling mechanism 500 (which is indicated by the solid line) than when not subjected to temperature adjustment by the cooling mechanism 500 (which is indicated by the broken line). As indicated by the solid line in FIG. 9, temperature adjustment carried out by the cooling mechanism 500 results in a temperature behavior approximate to that observed in the real vehicle simulation (which is indicated by the dotted line). As illustrated in FIG. 11, temperature adjustment carried out by the cooling mechanism 500 results in a resistance increase rate substantially equal to that observed in the real vehicle simulation. Accordingly, the electricity storage device evaluation apparatus 300 described above is able to easily and accurately evaluate the electricity storage device 1 in accordance with the predefined temperature change model.

In the electricity storage device evaluation apparatus 300 according to the above-described embodiment, each probe 100 includes a contact portion 111 that comes into direct contact with a corresponding one of the terminals 35, 45 of the electricity storage device 1. The cooling mechanism 500 includes the cooling fans 511, 512 to generate cooling air. The cooling mechanism 500 includes the outlets 520 each facing the lateral surface 110a of the corresponding probe 100 extending in the longitudinal direction of the probe 100 (i.e., the up-down direction Y). Thus, the cooling mechanism 500 is able to directly blow air onto each probe 100 that generates a high amount of heat. This results in further enhancement in the efficiency of cooling the electricity storage device 1.

In the electricity storage device evaluation apparatus 300 according to the above-described embodiment, each probe 100 has an area of 400 mm² or more in a vertical cross-section that passes through the central axis AX, which extends in the longitudinal direction of the probe 100, and that faces the corresponding one of the outlets 520. This enhances the effects of cooling air (i.e., cooling efficiency), resulting in a further reduction in the amount of heat generated by the probes 100.

In some embodiments, the lateral surface 110a of each probe 100 may be provided with a fin for heat dissipation. This makes it possible to more reliably reduce the amount of heat generated by each probe 100.

In the electricity storage device evaluation apparatus 300 according to the above-described embodiment, the cooling mechanism 500 is able to supply cooling air at an airflow rate of 1 m³/min or more. Accordingly, the evaluation apparatus 300 is able to enhance the efficiency of cooling the probes 100.

The use of the evaluation apparatus 300 disclosed herein enables efficient cooling of the electricity storage device 1 as previously described. Accordingly, the present disclosure provides an electricity storage device evaluation method. The electricity storage device evaluation method disclosed herein includes: bringing the probes 100 into abutment with the terminals 35, 45 of the electricity storage device 1 and placing the cooling mechanism 500 such that cooling air is blown onto the probes 100; passing a predetermined electric current to the electricity storage device 1 so as to charge or discharge the electricity storage device 1; measuring the temperatures T₀ and T₁ of the terminals 35, 45 of the electricity storage device 1 during charging or discharging; calculating the temperature increase ΔT of the terminals 35, 45 based on a temporal change from the temperature T₀ of the terminals 35, 45 (which is measured at the time t₀) to the temperature T₁ of the terminals 35, 45 (which is measured at the time t₁); and changing the airflow rate of cooling air in response to the calculated temperature increase ΔT. The evaluation method enables accurate evaluation of the electricity storage device 1 by simply bringing the evaluation apparatus 300 (or more specifically, the probes 100) into contact with the electricity storage device 1 (or more specifically, the terminals 35, 45) without welding the evaluation apparatus 300 to the electricity storage device 1. This results in a reduction in the number of steps required to evaluate of the electricity storage device 1, thus facilitating evaluation of the electricity storage device 1. Because the cooling mechanism 500 is able to blow cooling air onto the probes 100 that generate a high amount of heat, the evaluation method is able to efficiently cool the electricity storage device 1. The evaluation method is thus able to evaluate the electricity storage device 1 in an environment where the electricity storage device 1 is cooled with high cooling efficiency such that its temperature behavior approximates a predetermined temperature behavior. Consequently, the evaluation method is able to simply and accurately evaluate the electricity storage device 1.

In the above-described electricity storage device evaluation method, changing the airflow rate of cooling air includes performing feedback control to change the airflow rate of cooling air such that the temperature increase ΔT approximates that observed in the previously obtained temperature change model. Thus, the temperature increase ΔT falls within the preset allowable temperature range (Tₘᵢₙ to Tₘₐₓ). Consequently, the evaluation method is able to evaluate the electricity storage device 1 in an environment where its temperature behavior more closely approximates the predetermined temperature behavior.

The present disclosure will be described below with reference to a practical example and a comparative example. The following description, however, is not intended to limit the scope of the present disclosure to the practical example described below.

1. An electricity storage device evaluation apparatus comprising:
an electrically conductive probe;
a cooling mechanism; and
a controller, wherein
the probe is attached to an electricity storage device such that the probe abuts against a terminal exposed outside the electricity storage device,
the cooling mechanism is configured to blow cooling air onto the probe, with the probe being attached to the terminal,
the controller detects a temperature of the terminal of the electricity storage device, and
based on the temperature of the terminal, the controller adjusts an airflow rate of the cooling air supplied from the cooling mechanism.

2. The electricity storage device evaluation apparatus according to claim 1, wherein
the probe includes
a contact portion that comes into direct contact with the terminal of the electricity storage device, and
a lateral surface extending in a longitudinal direction of the probe, and
the cooling mechanism includes
a cooling fan to generate cooling air for cooling the probe, and
an outlet facing the lateral surface of the probe.

3. The electricity storage device evaluation apparatus according to claim 2, wherein
the probe has an area of 400 mm² or more in a vertical cross-section that passes through its central axis extending in the longitudinal direction of the probe and that faces the outlet.

4. The electricity storage device evaluation apparatus according to claim 2, wherein
the lateral surface of the probe is provided with a fin for heat dissipation.

5. The electricity storage device evaluation apparatus according to claim 1, wherein
the cooling mechanism is able to supply the cooling air to the probe at an airflow rate of 1 m³/min or more.

6. An electricity storage device evaluation method comprising:
bringing a probe into abutment with a terminal of an electricity storage device and placing a cooling mechanism such that cooling air is blown onto the probe;
supplying a predetermined electric current or voltage to the electricity storage device so as to charge or discharge the electricity storage device;
measuring a temperature of the terminal of the electricity storage device during charging or discharging;
calculating a temperature increase of the terminal based on a temporal change in the measured temperature of the terminal; and
changing an airflow rate of the cooling air in response to the calculated temperature increase.

7. The electricity storage device evaluation method according to claim 6, wherein
changing the airflow rate of the cooling air includes performing feedback control to change the airflow rate of the cooling air such that the temperature increase approximates that observed in a temperature change model obtained in advance.
